(19) United States
(12) Patent Application Publication
(10) Pub. No.: US 2026/0087213 A1
(43) Pub. Date: Mar. 26, 2026

(54) METHOD AND SYSTEM FOR SIMULATING EXTERNAL SHORT CIRCUIT OF BATTERY CELL

(71) Applicant: SAMSUNG SDI CO., LTD., Yongin-si (KR)

(72) Inventor: Taemyung KIM, Yongin-si (KR)

(21) Appl. No.: 19/320,682

(22) Filed: Sep. 5, 2025

(30) Foreign Application Priority Data
Sep. 25, 2024 (KR) 10-2024-0130062

(51) Int. Cl. G06F 30/30

(52) U.S. Cl. CPC G06F 30/30

(57) ABSTRACT

The present disclosure relates to a method and system for simulating an external short circuit of a battery cell. The method includes measuring a voltage, a current, and/or a temperature of a first cell upon the first cell being externally short-circuited, generating an external short circuit model that calculates a surface state of charge (SOC) based on the current and/or the temperature, and simulating an external short circuit of a second cell based on information about the first cell, information about the second cell, and/or an external short circuit resistance value applied to the second cell using a preset electrochemical model, a preset exothermic reaction model, a preset computational fluid dynamics model, and/or the external short circuit model.

### CROSS-REFERENCE TO RELATED APPLICATION

The present application claims priority to and the benefit under 35 U.S.C. § 119(a)-(d) of Korean Patent Application No. 10-2024-0130062, filed in the Korean Intellectual Property Office on Sep. 25, 2024, the entire disclosure of which is incorporated herein by reference.

### BACKGROUND

### 1. Field

The present disclosure relates to a method and system for simulating an external short circuit of a battery cell. More specifically, the present disclosure relates to a method and system form simulating the risk of an external short circuit of a second cell using experimental data of a first cell and a battery formula model.

### 2. Description of Related Art

In contrast to primary batteries that are not chargeable, secondary batteries are designed to be repeatedly discharged and recharged. Low-capacity rechargeable batteries are typically used in small portable electronic devices, such as smart phones, feature phones, notebook computers, digital cameras, and camcorders, while high-capacity rechargeable batteries are widely used as power sources for driving motors, such as of hybrid vehicles or electric vehicles, and for power storage. A secondary battery typically includes an electrode assembly including a positive electrode and a negative electrode, a case that accommodates the electrode assembly, a terminal part connected to the electrode assembly, etc.

With advanced vehicle specifications, batteries are becoming required with relatively greater energy densities than in the past. Specifically, high-nickel content batteries are being developed having a nickel content of 80 to 90%. The high-nickel content batteries are more and more required to have a nickel content even greater than 90% for high-specification vehicles.

On the one hand, as the nickel content increases, the energy density of the battery increases, resulting in a high-capacity battery. However on the other hand, the battery becomes more prone to safety risks. Among these risks is heat generation from excessive current in cells due to the existence of an external short circuit resistor.

Therefore, cell manufacturers are designing cells to mitigate such safety risks even when a predetermined level of an external short circuit resistor is present.

The information disclosed in this Background section is for enhancement of understanding of the background of the present disclosure. The section therefore may contain information that does not constitute a related (or prior) art.

### SUMMARY

Embodiments of the present disclosure provide a simulation method and system for predicting the risk of an external short circuit of a second cell using experimental data of a first cell and a battery equation model.

Embodiments of the present disclosure provide a system for simulating an external short circuit of a battery cell including an external short circuit experimental device configured to measure a voltage, current, and temperature of a first cell while the first cell is externally short-circuited and acquire experimental data, a first computing device configured to generate an external short circuit model that calculates a surface state of charge (SOC) when an applied current magnitude and temperature are input based on the experimental data, and a second computing device configured to perform simulation for an external short circuit of a second cell based on information about the first cell, information about the second cell, and an external short circuit resistance value applied to the second cell using a preset electrochemical model, a preset exothermic reaction model, a preset computational fluid dynamics model, and the external short circuit model.

Embodiments of the present disclosure provide a system including an external short circuit experimental device configured to measure a voltage, a current, and/or a temperature of a first cell upon the first cell being externally short-circuited; a first computing device configured to generate an external short circuit model that calculates a surface state of charge (SOC) based on the current and/or the temperature; and a second computing device configured to simulate an external short circuit of a second cell based on information about the first cell, information about the second cell, and/or an external short circuit resistance value applied to the second cell using a preset electrochemical model, a preset exothermic reaction model, a preset computational fluid dynamics model, and/or the external short circuit model.

In an embodiment, the external short circuit experimental device is configured to acquire data by applying one or more external short circuit resistors to the first cell.

In an embodiment, the external short circuit experimental device is configured to acquire data by measuring the voltage, the current, and/or the temperature of the first cell over time while the first cell is maintained as externally short-circuited.

In an embodiment, the external short circuit model calculates a capacity ratio of the first cell to a reference capacity based on the current and the temperature and calculates the surface SOC of the first cell based on the capacity ratio.

In an embodiment, the preset electrochemical model is based on an equivalent circuit model.

In an embodiment, the preset electrochemical model calculates heat generation of the second cell based on the surface SOC and a temperature calculated by the preset computational fluid dynamics model.

In an embodiment, the preset computational fluid dynamics model calculates a temperature of the second cell based on heat generation of the second cell calculated by the preset electrochemical model, and based on heat generation of the second cell calculated by the preset exothermic reaction model, and wherein the preset computational fluid dynamics model transfers the temperature of the second cell to the external short circuit model, the preset electrochemical model, and/or the preset exothermic reaction model.

In an embodiment, the preset exothermic reaction model outputs heat generation of a cell upon inputting a temperature of cell, and wherein the preset exothermic reaction model is based on data measured using an accelerated rate calorimeter.

In an embodiment, the information about the first cell includes a composition ratio of electrode plates of the first cell.

In an embodiment, the information about the second cell includes a composition ratio of electrode plates of the second cell and/or a shape of an internal component.

In an embodiment, the second computing device is configured to output a voltage profile of the second cell calculated by the preset electrochemical model.

In an embodiment, the second computing device is configured to output a temperature profile of the second cell calculated by the preset computational fluid dynamics model.

In an embodiment, the second computing device is configured to output a time zone-specific separator state of the second cell calculated by the preset computational fluid dynamics model.

In an embodiment, the second computing device is configured to determine an external short circuit limit resistance value of the second cell based on the external short circuit resistance value applied to the second cell and/or the temperature profile.

Embodiments of the present disclosure provide a method of simulating an external short circuit of a battery cell including measuring, by an external short circuit experimental device, a voltage, current, and temperature of a first cell while the first cell is externally short-circuited and acquiring experimental data, generating, by a first computing device, an external short circuit model that calculates a surface state of charge (SOC) when an applied current magnitude and temperature are input based on the experimental data, and performing, by a second computing device, simulation for an external short circuit of a second cell based on information about the first cell, information about the second cell, and an external short circuit resistance value applied to the second cell using a preset electrochemical model, a preset exothermic reaction model, a preset computational fluid dynamics model, and the external short circuit model.

Embodiments of the present disclosure provide a method including: measuring, by an external short circuit experimental device, a voltage, a current, and/or a temperature of a first cell upon the first cell being externally short-circuited; generating, by a first computing device, an external short circuit model that calculates a surface state of charge (SOC) based on the current and/or the temperature; and simulating, by a second computing device, an external short circuit of a second cell based on information about the first cell, information about the second cell, and/or an external short circuit resistance value applied to the second cell using a preset electrochemical model, a preset exothermic reaction model, a preset computational fluid dynamics model, and/or the external short circuit model.

In an embodiment, the external short circuit model calculates a capacity ratio of the first cell to a reference capacity based on the current and the temperature and calculates the surface SOC of the first cell based on the capacity ratio.

In an embodiment, the preset electrochemical model calculates heat generation of the second cell based on the surface SOC and a temperature calculated by the preset computational fluid dynamics model.

In an embodiment, the preset computational fluid dynamics model calculates a temperature of the second cell based on heat generation of the second cell calculated by the preset electrochemical model, and based on heat generation of the second cell calculated by the preset exothermic reaction model, and wherein the preset computational fluid dynamics model transfers the temperature of the second cell to the external short circuit model, the preset electrochemical model, and/or the preset exothermic reaction model.

In an embodiment, the simulating includes outputting a temperature profile of the second cell calculated by the preset computational fluid dynamics model.

In an embodiment, the simulating further includes determining an external short circuit limit resistance value of the second cell based on the external short circuit resistance value applied to the second cell and/or the temperature profile.

### BRIEF DESCRIPTION OF THE DRAWINGS

The following drawings attached to this specification illustrate embodiments of the present disclosure, and describe aspects and features of the present disclosure together with the detailed description of the present disclosure. The present disclosure is not limited to embodiments depicted in the drawings.

FIG. 1 is a block diagram showing a system for simulating an external short circuit of a battery cell according to an embodiment of the present disclosure;

FIG. 2 is a schematic view showing an external short circuit experimental device according to an embodiment of the present disclosure;

FIG. 3 is a flowchart showing a method of simulating an external short circuit of a battery cell according to an embodiment of the present disclosure;

FIG. 4 is a graphical representation showing a surface state of charge (SOC) introduced into an external short circuit model according to an embodiment of the present disclosure;

FIG. 5 is a block diagram showing a calculation process of a second computing device according to an embodiment of the present disclosure;

FIG. 6 is graphical representation of an exothermic reaction model according to an embodiment of the present disclosure;

FIG. 7 is a schematic view showing temperature distribution data of a battery cell according to an embodiment of the present disclosure;

FIG. 8 is graphical representation showing a temperature profile of the battery cell according to an embodiment of the present disclosure;

FIG. 9 is schematic view showing a separator state for each external short circuit resistor according to an embodiment of the present disclosure; and

FIG. 10 is a block diagram showing a computer system for implementing a method according to an embodiment of the present disclosure.

### DETAILED DESCRIPTION

Hereinafter, embodiments of the present disclosure will be described, in detail, with reference to the accompanying drawings. The terms or words used in the present specification and claims are not to be narrowly interpreted according to their general or dictionary meanings and should be interpreted as having meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some embodiments of the present disclosure and do not represent all of the aspects, features, and embodiments of the present disclosure. Accordingly, it should be understood that there may be various equivalents and modifications that can replace or modify one or more embodiments or features therein described herein at the time of filing this application.

When an element is referred to as being on another element, the element can be directly on the other element or intervening elements may be present between therebetween. In the drawings, thicknesses of some components can be exaggerated for effectively explaining the technical contents. Like reference numerals refer to like elements throughout the specification.

The embodiments described herein can be explained with reference to cross-sectional views and/or plan views as example views of the present disclosure. In the drawing, the thicknesses of films and regions can be exaggerated for effective description of technical contents. Thus, regions presented as an example in the drawings have general properties, and shapes of the exemplified areas can be used to illustrate a specific shape of a device region. Therefore, this should not be construed as limited to the scope of the present disclosure. Although the terms such as first, second, and third are used to describe various components in various embodiments herein, the components should not be limited to these terms. These terms are used only to distinguish one component from another component. Embodiments described and exemplified herein include complementary embodiments thereof.

It will be understood that if an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, if a first element is described as being “coupled” or “connected” to a second element, the first element may be directly coupled or connected to the second element or the first element may be indirectly coupled or connected to the second element via one or more intervening elements.

As used herein, the term “and/or” includes any and all combinations of one or more of the associated listed items. Further, the use of “may” if describing embodiments of the present disclosure relates to “one or more embodiments of the present disclosure.” Expressions, such as “at least one of” and “any one of,” if preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” if used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same.” Thus, the phrase “substantially the same” may include a case having a deviation that is considered low in the art, for example, a deviation of 5% or less. In addition, if a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may contact the upper (or lower) surface of the element, and another element may also be interposed between the element and the arbitrary element located on (or under) the element.

In addition, it will be understood that if a component is referred to as being “linked,” “coupled,” or “connected” to another component, the elements may be directly “coupled,” “linked” or “connected” to each other, or another component may be “interposed” between the components.”

Throughout the specification, if “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terminology used herein is for the purpose of describing embodiments of the present disclosure and is not intended to limit the present disclosure.

Embodiments of the disclosure provide a method and system for simulating an external short circuit of a battery cell arranging a first cell as an experimental object in a chamber, applies an external short circuit resistor to the first cell to acquire experimental data for each external short circuit resistor, and generates an external short circuit model using the acquired experimental data. Advantageously, it is possible to predict an external short circuit limit resistance of a second cell and predict a change in characteristics of the second cell due to thermal runaway using the external short circuit model, electrode plate information of the first cell, form factor information of the second cell as an experimental object, and a heat generation characteristic model of a cell.

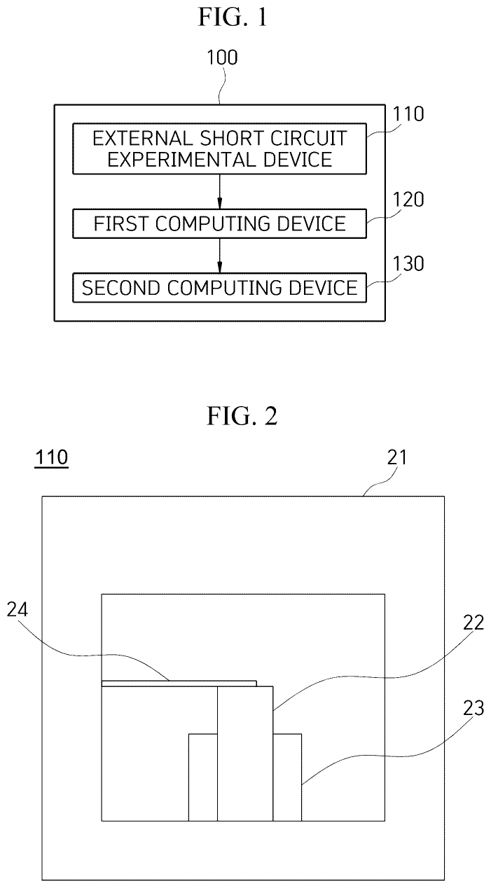

FIG. 1 is a block diagram showing a system for simulating an external short circuit of a battery cell according to an embodiment of the present disclosure.

In an embodiment, a system 100 for simulating an external short circuit of a battery cell is composed of an external short circuit experimental device 110, a first computing device 120, and a second computing device 130. Components of the system 100 for simulating an external short circuit of a battery cell are not limited to the embodiment shown in FIG. 1 and may be added, changed, or omitted as needed. In an embodiment, the first computing device 120 and the second computing device 130 may be integrated into one computing device. In addition, a function of the second computing device 130 may be changed by being distributed and performed across multiple computing devices.

The external short circuit experimental device 110 is configured to acquire experimental data by measuring a voltage, current, and temperature of the first cell at predetermined time intervals while the first cell is externally short-circuited. The external short circuit experimental device 110 may transmit the experimental data to the first computing device 120 through a built-in communication device (not shown).

FIG. 2 is a schematic view showing an external short circuit experimental device according to an embodiment of the present disclosure. The external short circuit experimental device 110 has a structure in which the first cell 22 is disposed in a chamber 21 and insulation bulkheads 23 are disposed at both sides of the first cell 22. In addition, a measurement cable 24 is connected to a terminal of the first cell 22. A measurement cable 24 is used to measure the voltage, current, and temperature of the first cell 22 during an external short circuit experiment using the external short circuit experimental device 110.

Since the present disclosure is drawn to predicting results related to an external short circuit of a second cell (not shown) using the result of the external short circuit experiment of a first cell 22, the first cell 22 may be a small-sized cell and the second cell may be a medium-sized or large-sized cell. There is no limitation to shapes (e.g., prismatic, cylindrical, or pouch-shaped) of the first cell 22 and the second cell.

In an embodiment, the external short circuit experimental device 110 is configured to acquire experimental data by applying an external short circuit resistor to the first cell 22.

The experimental data may be acquired by applying a plurality of external short circuit resistors with various resistance values to the external short circuit experiment of the first cell 22.

In addition, the experimental data may be acquired by measuring the voltage, current, and temperature of the first cell 22 over time while the first cell 22 is externally short-circuited.

Returning back to FIG. 1, the first computing device 120 generates an external short circuit model based on the experimental data acquired by the external short circuit experimental device 110. The external short circuit model is a model that calculates a surface state of charge (SOC) when current magnitude (C-rate) and temperature are applied. In an embodiment, the external short circuit model is a model that calculates a capacity ratio of the first cell 22 to a reference capacity according to the applied current magnitude and temperature and the surface SOC of the first cell 22 is calculated based on the capacity ratio. The applied current magnitude (C-rate) is a rate at which a battery is charged or discharged.

The second computing device 130 performs simulation of an external short circuit of the second cell based on information about the first cell, information about the second cell, and an external short circuit resistance value applied to the second cell using a preset electrochemical model, a preset exothermic reaction model, a preset computational fluid dynamics model, and the external short circuit model generated by the first computing device 120.

The information about the first cell includes information about electrode plates of the first cell. The information about the electrode plates of the first cell includes a composition ratio (e.g., Ni91V2) of the electrode plate.

The information about the second cell includes information about the electrode plates of the second cell and/or information about a form factor of the second cell. The information about the electrode plates of the second cell includes a composition ratio of the electrode plates of the second cell, and/or the information about the form factor of the second cell includes at least one of the cell size, the cell capacity, and shapes of internal components.

Cell size is related to cell capacity.

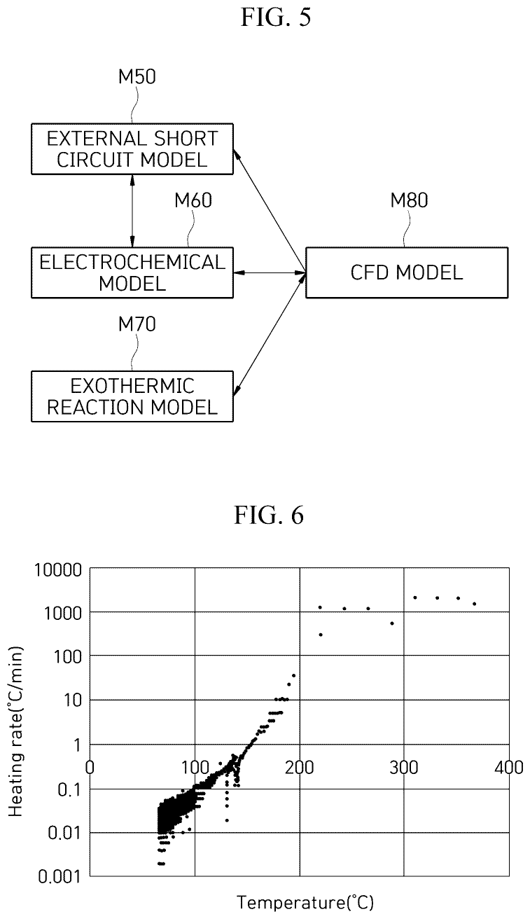

FIG. 5 is a block diagram showing a calculation process of a second computing device according to an embodiment of the present disclosure.

Referring to FIGS. 1 and 5, the electrochemical model M60 is a model based on an equivalent circuit model and is a model that calculates a heat generation amount of the second cell based on a surface SOC calculated by the external short circuit model M50 and the temperature of the second cell calculated by a computational fluid dynamics (CFD) model M80. In addition, the electrochemical model M60 may generate a voltage profile (data on a change in voltage over time) of the second cell based on the input data.

The exothermic reaction model M70 is a model that outputs a heat generation amount of the battery cell when the temperature of the battery cell is input and is a model constructed based on experimental data measured using an accelerated rate calorimeter (ARC) through exothermic reaction experiments.

The computational fluid dynamics model M80 calculates the temperature of the second cell based on the heat generation amount of the second cell calculated by the electrochemical model M60 and the heat generation amount of the second cell calculated by the exothermic reaction model M70 and transfers the temperature of the second cell to the external short circuit model M50, the electrochemical model M60, and the exothermic reaction model M70. The computational fluid dynamics model M80 may predict the temperature distribution, temperature profile, and separator state (shutdown/melting or the like) of the second cell based on the input data.

The second computing device 130 may output a voltage profile of the second cell 32 calculated by the electrochemical model M60. In addition, the second computing device 130 may output the temperature distribution, temperature profile, and time zone-specific separator state of the second cell 32 predicted by the computational fluid dynamics model M80.

In addition, the second computing device 130 may determine and output an external short circuit limit resistance value of the second cell based on the external short circuit resistance value applied to the second cell and the temperature distribution, temperature profile, or separator state of the second cell predicted by the computational fluid dynamics model M80. For example, when a resistor having a specific external short circuit resistance value or less is applied to the second cell, when the temperature of the second cell exceeds a reference value or the separator state reaches a shutdown state, the second computing device 130 may determine that the specific external short circuit resistance value is the external short circuit limit resistance value.

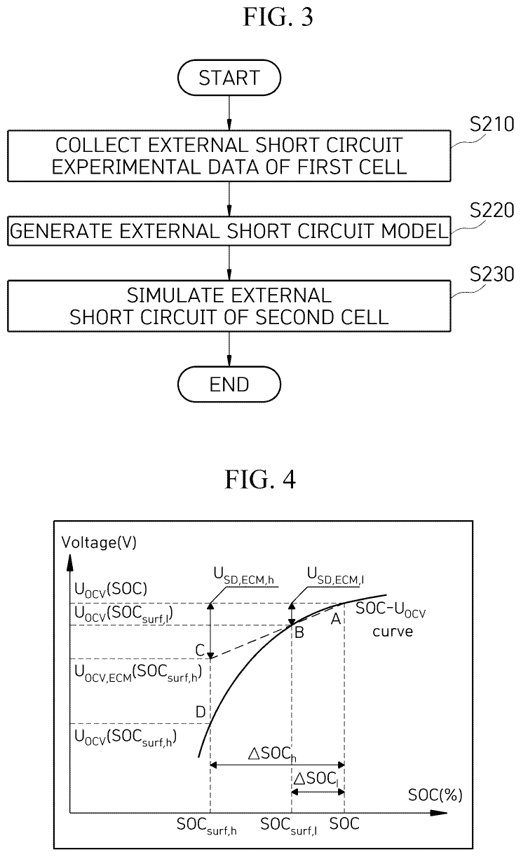

FIG. 3 is a flowchart showing a method of simulating an external short circuit of a battery cell according to an embodiment of the present disclosure.

In an embodiment, the method of simulating an external short circuit of a battery cell includes operations S210 to S230. Operations of the method of simulating an external short circuit of a battery cell according to the present disclosure are not limited to the embodiment shown in FIG. 3 and may be added, changed, or omitted as needed.

Operation S210 is an operation of collecting experimental data by applying an external short circuit resistor to the first cell.

Referring to FIGS. 1 and 3, the external short circuit experimental device 110 acquires experimental data by measuring a voltage, current, and temperature of the first cell at predetermined time intervals while the first cell is externally short-circuited. The external short circuit experimental device 110 may transmit the experimental data to the first computing device 120 through a built-in communication device.

The experimental data may be acquired by applying a plurality of external short circuit resistors with different resistance values to the external short circuit experiment of the first cell.

In addition, the experimental data may be acquired by measuring the voltage, current, and temperature of the first cell over time while the first cell is externally short-circuited. In an embodiment, the experimental data may include a voltage of the first cell, a temperature of a vent, a temperature of a positive (+) electrode terminal, a temperature of a negative (−) electrode terminal, an ambient temperature, and a current.

Table 1 shows an example of experimental data measuring the voltage, the temperature of the vent, the temperature of the positive electrode terminal, the temperature of the negative electrode terminal, and the ambient temperature among the experimental data. Table 2 shows an example of experimental data measuring the voltage and current among the experimental data. The unit of temperature is Celsius.

TABLE 1

| | #1 Cell | | | | |
|---|---|---|---|---|---|
| | | | Temperature | Temperature | |
| | | Temper- | of positive | of negative | Ambient |
| | | ature | electrode | electrode | temper- |
| Time(min) | Voltage | of vent | terminal | terminal | ature |
| 0 | 4.20 | 24.79 | 24.79 | 25.06 | 24.25 |
| 0.1 | 4.20 | 24.66 | 24.86 | 25.20 | 24.25 |
| 0.2 | 2.77 | 24.79 | 24.86 | 25.20 | 24.12 |
| 0.3 | 2.34 | 24.86 | 27.02 | 26.28 | 24.05 |

TABLE 2

#1 Cell

| time(min) | Voltage | Current |
|---|---|---|
| 0 | 4.20 | −6.25 |
| 0.05 | 4.20 | −5.63 |
| 0.10 | 4.20 | −6.25 |
| 0.15 | 4.20 | −6.88 |
| 0.20 | 2.71 | 2844 |

As can be seen in Table 2, after 0.2 minutes, the current increased rapidly due to the external short circuit of the cell.

Operation S220 is an operation of generating an external short circuit model.

Referring to FIGS. 1, 3, and 5, the first computing device 120 generates the external short circuit model M50 based on the experimental data acquired in operation S210. The external short circuit model M50 is a model that calculates the capacity ratio of the first cell to the reference capacity (rated capacity) when the applied current magnitude (C-rate) and temperature are input and calculates the surface SOC of the first cell based on the capacity ratio.

FIG. 4 is a graphical representation showing a surface state of charge (SOC) introduced into an external short circuit model according to an embodiment of the present disclosure. In an embodiment, the external short circuit model guides the electrochemical model to calculate a predicted value more accurately by inputting a corrected SOC (surface SOC) instead of inputting the SOC into the electrochemical model in the external short circuit simulation of the second cell. The surface SOC represents a lithium concentration of a particle surface. The dashed line in FIG. 4 represents a change in voltage (A-B-C) when it is assumed that the applied current magnitude (C-rate) of a design range is applied and the SOC changes normally. The curve in FIG. 4 represents a rapid change in voltage (A-B-D) when an unusual applied current magnitude (C-rate) is applied. That is, when the applied current magnitude (C-rate) applied to the battery cell is unusual, such as an external short circuit, a voltage may drop further compared to a preset reference, and in this case, the capacity calculated as the result of current accumulation is lowered. Therefore, referring to FIGS. 4 and 5, it is necessary to guide the electrochemical model M60 to make a more suitable prediction for reality by correcting the SOC according to the applied current magnitude (C-rate) and transferring the corrected SOC to the electrochemical model M60, and in the present disclosure, the external short circuit model M50 plays the role.

To conduct external short circuit analysis (simulation) of the second cell as a prediction object cell, an output of the external short circuit model M50 needs to be transferred as an input of the electrochemical model M60.

Referring to FIGS. 1-5, the electrochemical model M60 used by the second computing device 130 estimates parameters such as a voltage, current, and resistance of the cell based on the temperature and SOC of the cell. The external short circuit model M50 functions to correct the SOC of the cell by applying a variable capacity ratio according to the applied current magnitude (C-rate) and temperature and transfer the corrected SOC (surface SOC (SSOC)) to the electrochemical model M60.

The first computing device 120 fits the external short circuit model M50 using the external short circuit experimental data (data on the current, voltage, and temperature over time) of the first cell 22 acquired by the external short circuit experimental device 110. The first computing device 120 estimates the applied current magnitude (C-rate) and temperature-specific capacity ratio used in the external short circuit model M50 based on the external short circuit experimental data of the first cell 22.

In an embodiment, the external short circuit model M50 can include a model M50-1 (not shown) that generates a capacity ratio parameter according to the applied current magnitude (C-rate) and temperature based on the experimental data, and can include a model M50-2 (not shown) that calculates an SOC, in an embodiment, an SSOC, required for the electrochemical analysis of the electrochemical model M60 using the capacity ratio parameter.

With respect to the capacity ratio calculation model M50-1, the first computing device 120 calculates the capacity according to the temperature and applied current magnitude (C-rate) of the first cell 22 based on the experimental data of the external short circuit experimental device 110. Table 3 shows an example of the result of calculating the capacity.

TABLE 3

| | | C-rate | | | | | |
|---|---|---|---|---|---|---|---|
| Q (capacity) | | 0.2 | 0.33 | 0.5 | 1 | 2 | 3 |
| Temper- | 15 | 2.365 | 2.3067 | 2.2766 | 1.8285 | 0.7582 | 0.4088 |
| ature | 25 | 2.4111 | 2.3742 | 2.3473 | 2.2220 | 1.1235 | 0.6432 |
| (° C.) | | | | | | | |

The first computing device 120 generates a capacity ratio table according to the temperature and applied current magnitude (C-rate) by dividing the result of calculating the capacity by the rated capacity. Table 4 shows an example of a capacity ratio table. A capacity ratio table is generated by the first computing device 120 dividing the capacity Q of Table 3 by the rated capacity when the rated capacity of the first cell is 2.325.

TABLE 4

| Q_coef | | C-rate | | | | | |
|---|---|---|---|---|---|---|---|
| (capacity ratio) | | 0.2 | 0.33 | 0.5 | 1 | 2 | 3 |
| Temper- | 15 | 1.0092 | 0.9921 | 0.9792 | 0.7865 | 0.3261 | 0.1758 |
| ature | 25 | 1.0370 | 1.0212 | 1.0096 | 0.9557 | 0.4832 | 0.2766 |
| (° C.) | | | | | | | |

The first computing device 120 may calculate a capacity ratio a of an experimental section and a non-experimental section using linear interpolation based on the capacity ratio table (M50-1).

The capacity ratio a calculated by the first computing device 120 is used in the SSOC calculation model M50-2 using Equations 1 to 3.

$$x = \frac{( Initial SOC - Present SOC )}{a} \qquad [ Equation 1 ]$$

$$Δ SOC = - ( 1 - {( 100 - 100 a )}^{x} ) \qquad [ Equation 2 ]$$

$$SSOC = SOC - Δ SOC \qquad [ Equation 3 ]$$

where x denotes an SOC usage with respect to the capacity and has a value between 0 and 1. Initial SOC is an initial SOC, and Present SOC is an SOC of a previous time step at the current time of the analysis. ΔSOC is a value for adjusting an SOC, and when ΔSOC is subtracted from the SOC, a corrected value SSOC of the SOC to be transferred to the electrochemical model M60 is calculated. The SSOC calculation model M50-2 is a model that handles calculation up to the process of calculating an SSOC based on the capacity ratio a.

The operation S230 is an operation of performing simulation for an external short circuit of the second cell.

The second computing device 130 performs simulation of the external short circuit of the second cell based on the information about the first cell 22, the information about the second cell, and the external short circuit resistance value applied to the second cell using the preset electrochemical model, the preset exothermic reaction model, the preset computational fluid dynamics model, and the external short circuit model generated by the first computing device 120 in operation S220, thereby predicting the temperature distribution, temperature profile, voltage profile, separator state (shutdown/melting or the like), and whether thermal runaway occurs at the time of the external short circuit of the second cell.

The information about the first cell 22 includes information about electrode plates of the first cell 22. The information about the electrode plates of the first cell 22 includes a composition ratio (e.g., Ni91V2) of the electrode plates.

The information about the second cell includes information about the electrode plates and/or information about a form factor of the second cell. The information about the electrode plates of the second cell includes a composition ratio of the electrode plates of the second cell 32, and/or the information about the form factor of the second cell includes at least one of the cell size, the cell capacity, and shapes of internal components.

In an embodiment, the second computing device 130 inputs the information about the electrode plates of the second cell into the external short circuit model M50, the electrochemical model M60, the exothermic reaction model M70, and the computational fluid dynamics model M80. The second computing device 130 inputs the information about the electrode plates of the first cell 22 and the information about the form factor of the second cell into the electrochemical model M60. In this case, the electrochemical model M60 uses both the information about the electrode plates of the first cell 22 and the information about the electrode plates of the second cell.

In addition, the second computing device 130 inputs the external short circuit resistance value applied to the second cell into the electrochemical model M60. The second computing device 130 may input various external short circuit resistance values into the electrochemical model M60 and acquire simulation results (temperature distribution, temperature profile, voltage profile, separator state, and the like) for each external short circuit resistor from each of the models M50 to M80.

The external short circuit model M50 calculates the capacity ratio based on the applied current magnitude (C-rate) input from the electrochemical model M60 and the temperature of the second cell 32 input from the computational fluid dynamics model M80, and calculates the corrected SOC (SSOC) based on the capacity ratio and transfers the SSOC to the electrochemical model M60.

The electrochemical model M60 is a model based on an equivalent circuit model and is a model that calculates the heat generation amount and voltage of the second cell based on the SSOC calculated by the external short circuit model M50 and the temperature of the second cell calculated by the computational fluid dynamics model M80. The electrochemical model M60 may generate a voltage profile based on a voltage value over time.

The exothermic reaction model M70 is a model that outputs a heat generation amount of the battery cell when the temperature of the battery cell is input and is a model constructed based on experimental data measured using an accelerated rate calorimeter (ARC) through exothermic reaction experiments. The exothermic reaction model M70 receives the temperature of the second cell and outputs a heat generation amount of the second cell. FIG. 6 is graphical representation of an exothermic reaction model M70 according to an embodiment of the present disclosure, and the exothermic reaction model M70 may have a form of a table or equation model.

Referring to FIGS. 1-6, the computational fluid dynamics model M80 (CFD model) calculates the temperature of the second cell based on the heat generation amount of the second cell calculated by the electrochemical model M60 and the heat generation amount of the second cell calculated by the exothermic reaction model M70 and transfers the temperature of the second cell to the external short circuit model M50, the electrochemical model M60, and the exothermic reaction model M70.

Since the exothermic reaction model M70 is a model constructed based on actual experiments, the heat generation amount data in a case in which an abnormal exothermic reaction occurs in a battery cell is reflected. Therefore, the computational fluid dynamics model M80 may calculate the temperature of the second cell by correcting the heat generation amount calculated by the electrochemical model M60 based on the heat generation amount of the exothermic reaction model M70 or calculating the final heat generation amount through the weighted sum of the heat generation amount calculated by the electrochemical model M60 and the heat generation amount calculated by the exothermic reaction model M70. In addition, the computational fluid dynamics model M80 may use only the heat generation amount calculated by the exothermic reaction model M70 as the heat generation amount that is the basis for calculating the temperature of the second cell when a ratio of the heat generation amount calculated by the electrochemical model M60 and the heat generation amount calculated by the exothermic reaction model M70 exceeds a predetermined reference value. That is, since the electrochemical model M60 may have a disadvantage in predicting the heat generation amount when the second cell is abnormal, the exothermic reaction model M70 is intended to be introduced to compensate for such a disadvantage.

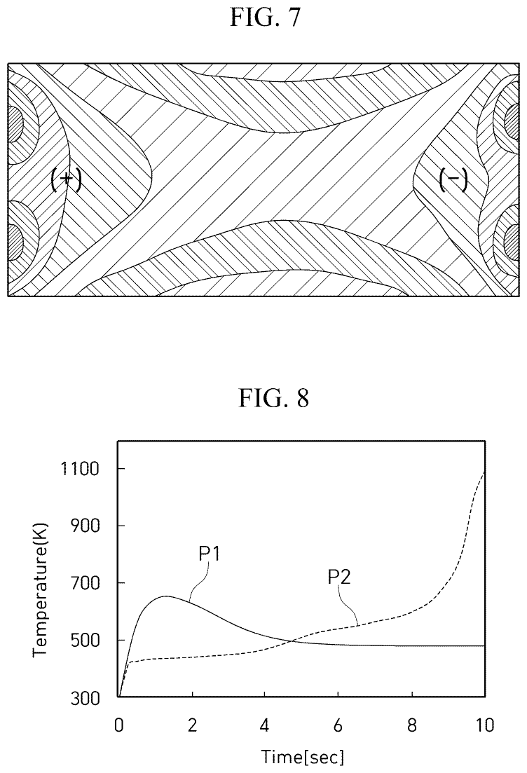

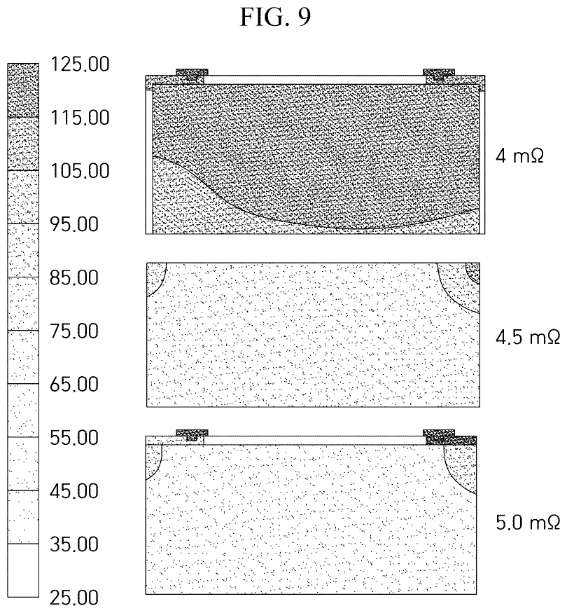

The computational fluid dynamics model M80 may calculate the temperature distribution (see FIG. 7), temperature profile (see FIG. 8, where P1 and P2 are examples of different profiles), and separator state (shutdown/melting or the like) of the second cell 32 based on the result of calculating the temperature of the second cell 32. FIG. 9 is schematic view showing a separator state for each external short circuit resistor according to an embodiment of the present disclosure.

Referring to FIGS. 1-9, the second computing device 130 may output the voltage profile of the second cell calculated by the electrochemical model M60, the temperature distribution, temperature profile, time zone-specific separator state, and the like of the second cell calculated by the computational fluid dynamics model M80 as the result of simulating the external short circuit of the second cell in the form of a display, file, or the like.

In addition, the second computing device 130 may determine and output an external short circuit limit resistance value of the second cell based on the external short circuit resistance value applied to the second cell and the temperature distribution, temperature profile, or separator state of the second cell predicted by the computational fluid dynamics model M80. In an embodiment, when a resistor having a specific external short circuit resistance value or less is applied to the second cell, when the temperature of the second cell exceeds a reference value or the separator state reaches a shutdown state, the second computing device 130 may determine that the specific external short circuit resistance value is the external short circuit limit resistance value.

The method of simulating an external short circuit of a battery cell has been described with reference to the flowchart presented in the drawings. For simplicity, the method has been shown and described as a series of blocks, but the present disclosure is not limited to the order of the blocks, some blocks may occur in a different order or simultaneously with other blocks shown and described herein, and various other branches, flow paths, and block orders that achieve the same or similar results may be implemented. In addition, not all of the shown blocks may be required for implementing the method described herein.

Meanwhile, in the description with reference to FIGS. 3 to 9, each operation may be further subdivided into a larger number of additional operations or combined into a fewer number of operations according to the embodiments of the present disclosure. In addition, some operations may be omitted as needed, or the order between the operations may be changed. In addition, although other content is omitted, the content of FIGS. 1 and 2 may be applied to the content of FIG. 3. In addition, the content of FIGS. 3 to 9 may be applied to the content of FIGS. 1 and 2.

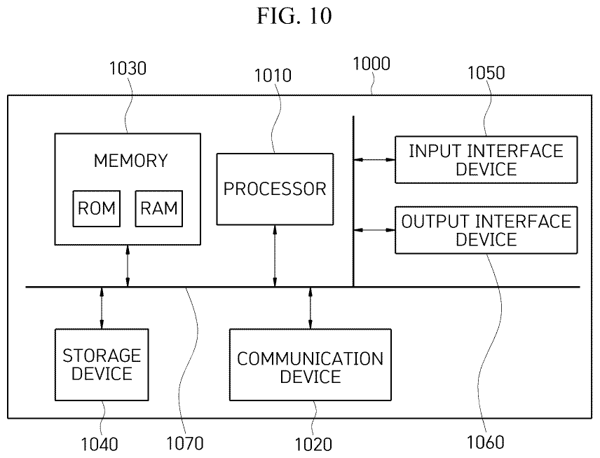

FIG. 10 is a block diagram showing a computer system for implementing a method according to an embodiment of the present disclosure.

Referring to FIGS. 1 and 10, in an embodiment, the first computing device 120 and the second computing device 130 may be implemented in the form of a computer system 1000.

The computer system 1000 may include at least one of one or more processors 1010, a memory 1030, an input interface device 1050, an output interface device 1060, and a storage device 1040 that communicate via a bus 1070. The computer system 1000 may further include a communication device 1020 coupled to a network.

The processor 1010 may be a central processing unit (CPU), or a semiconductor device that executes computer-readable commands stored in the memory 1030 or the storage device 1040. The processor 1010 may perform the calculation function of the first computing device 120 or the second computing device 130.

The memory 1030 and the storage device 1040 may include various types of volatile or nonvolatile storage media. In an embodiment, the memory 1030 may include a read only memory (ROM) and a random access memory (RAM). In the embodiment of the present disclosure, the memory 1030 may be positioned inside or outside the processor 1010, and the memory 1030 may be connected to the processor 1010 through various means already known. The memory 1030 may be various types of volatile or nonvolatile storage media, and for example, the memory 1030 may include a ROM or a RAM.

The memory 1030 or the storage device 1040 may store data and models (e.g., M50, M60, M70, and M80 of FIG. 5) received or used by the first computing device 120 and the second computing device 130.

Therefore, the embodiment of the present disclosure may be implemented as a method implemented on a computer or as a non-transitory computer-readable medium storing computer-executable commands. In an embodiment, when executed by the processor 1010, the computer-readable commands may perform a method according to at least one aspect of the present disclosure.

The communication device 1020 may transmit or receive a wired signal or a wireless signal.

In addition, the method of simulating an external short circuit of a battery cell according to the embodiment of the present disclosure may be implemented in the form of program commands that may be performed through various computer devices and recorded on a computer-readable medium.

The computer-readable medium may include program commands, data files, data structures, and the like alone or in combination. The program commands recorded on the computer-readable recording medium may be specially designed and configured for the embodiments of the present disclosure or may be known and available to those skilled in the field of computer software. The computer-readable recording medium may include a hardware device configured to store and perform the program commands. For example, the computer-readable recording medium may include magnetic media such as a hard disk, a floppy disk, and a magnetic tape, optical media such as a CD-ROM and a DVD, and magneto-optical media such as a floptical disk, a ROM, a RAM, and a flash memory. The program commands include not only machine language code such as that produced by a compiler but also high-level language code that may be executed by a computer using an interpreter or the like.

Although the content is omitted from the description with reference to FIG. 10, the content of FIGS. 1 to 9 may be applied to the content of FIG. 10. In addition, the content of FIG. 10 may be applied to the content of FIGS. 1 to 9.

According to one embodiment of the present disclosure, since an external short circuit risk for a cell having various other form factors can be predicted using the result of testing an external short circuit of a small cell, it is possible to enable risk prediction before manufacturing cells, thereby increasing design efficiency and saving design cost.

In addition, according to one embodiment of the present disclosure, it is possible to automate the prediction for an external short circuit result in connection with an evaluation device and a data library, and shorten a development period of a cell through automated risk verification.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure.

What is claimed is:

1. A system, comprising:
an external short circuit experimental device configured to measure a voltage, a current, and/or a temperature of a first cell upon the first cell being externally short-circuited;
a first computing device configured to generate an external short circuit model that calculates a surface state of charge (SOC) based on the current and/or the temperature; and
a second computing device configured to simulate an external short circuit of a second cell based on information about the first cell, information about the second cell, and/or an external short circuit resistance value applied to the second cell using a preset electrochemical model, a preset exothermic reaction model, a preset computational fluid dynamics model, and/or the external short circuit model.

2. The system as claimed in claim 1, wherein the external short circuit experimental device is configured to acquire data by applying one or more external short circuit resistors to the first cell.

3. The system as claimed in claim 1, wherein the external short circuit experimental device is configured to acquire data by measuring the voltage, the current, and/or the temperature of the first cell over time while the first cell is maintained as externally short-circuited.

4. The system as claimed in claim 1, wherein the external short circuit model calculates a capacity ratio of the first cell to a reference capacity based on the current and the temperature and calculates the surface SOC of the first cell based on the capacity ratio.

5. The system as claimed in claim 1, wherein the preset electrochemical model is based on an equivalent circuit model.

6. The system as claimed in claim 1, wherein the preset electrochemical model calculates heat generation of the second cell based on the surface SOC and a temperature calculated by the preset computational fluid dynamics model.

7. The system as claimed in claim 1, wherein the preset computational fluid dynamics model calculates a temperature of the second cell based on heat generation of the second cell calculated by the preset electrochemical model, and based on heat generation of the second cell calculated by the preset exothermic reaction model, and wherein the preset computational fluid dynamics model transfers the temperature of the second cell to the external short circuit model, the preset electrochemical model, and/or the preset exothermic reaction model.

8. The system as claimed in claim 1, wherein the preset exothermic reaction model outputs heat generation of a cell upon inputting a temperature of cell, and wherein the preset exothermic reaction model is based on data measured using an accelerated rate calorimeter.

9. The system as claimed in claim 1, wherein the information about the first cell comprises a composition ratio of electrode plates of the first cell.

10. The system as claimed in claim 1, wherein the information about the second cell comprises a composition ratio of electrode plates of the second cell and/or a shape of an internal component.

11. The system as claimed in claim 1, wherein the second computing device is configured to output a voltage profile of the second cell calculated by the preset electrochemical model.

12. The system as claimed in claim 1, wherein the second computing device is configured to output a temperature profile of the second cell calculated by the preset computational fluid dynamics model.

13. The system as claimed in claim 1, wherein the second computing device is configured to output a time zone-specific separator state of the second cell calculated by the preset computational fluid dynamics model.

14. The system as claimed in claim 12, wherein the second computing device is configured to determine an external short circuit limit resistance value of the second cell based on the external short circuit resistance value applied to the second cell and/or the temperature profile.

15. A method, comprising:
measuring, by an external short circuit experimental device, a voltage, a current, and/or a temperature of a first cell upon the first cell being externally short-circuited;
generating, by a first computing device, an external short circuit model that calculates a surface state of charge (SOC) based on the current and/or the temperature; and
simulating, by a second computing device, an external short circuit of a second cell based on information about the first cell, information about the second cell, and/or an external short circuit resistance value applied to the second cell using a preset electrochemical model, a preset exothermic reaction model, a preset computational fluid dynamics model, and/or the external short circuit model.

16. The method as claimed in claim 15, wherein the external short circuit model calculates a capacity ratio of the first cell to a reference capacity based on the current and the temperature and calculates the surface SOC of the first cell based on the capacity ratio.

17. The method as claimed in claim 15, wherein the preset electrochemical model calculates heat generation of the second cell based on the surface SOC and a temperature calculated by the preset computational fluid dynamics model.

18. The method as claimed in claim 15, wherein the preset computational fluid dynamics model calculates a temperature of the second cell based on heat generation of the second cell calculated by the preset electrochemical model, and based on heat generation of the second cell calculated by the preset exothermic reaction model, and wherein the preset computational fluid dynamics model transfers the temperature of the second cell to the external short circuit model, the preset electrochemical model, and/or the preset exothermic reaction model.

19. The method as claimed in claim 15, wherein the simulating comprises outputting a temperature profile of the second cell calculated by the preset computational fluid dynamics model.

20. The method as claimed in claim 19, wherein the simulating further comprises determining an external short circuit limit resistance value of the second cell based on the external short circuit resistance value applied to the second cell and/or the temperature profile.
